(19) United States
(12) Patent Application Publication
(10) Pub. No.: US 2026/0059694 A1
(43) Pub. Date: Feb. 26, 2026

(54) DYNAMIC FAN OPERATION IN ELECTRONIC DEVICES

(71) Applicant: Charter Communications Operating, LLC, St. Louis, MO (US)

(72) Inventors: Michael Brian Detty, Lafayette, CO (US); Taren McCullough, Plymouth, MN (US); Ivan Ivanovich Grinev, Washougal, WA (US)

(73) Assignee: Charter Communications Operating, LLC, St. Louis, MO (US)

(21) Appl. No.: 18/813,857

(22) Filed: Aug. 23, 2024

(51) Int. Cl. H05K 7/20; H05K 5/02

(52) U.S. Cl. CPC H05K 7/20209; H05K 5/0213; H05K 7/20136

(57) ABSTRACT

Methods, devices, and systems for dynamically controlling airflow in an electronic device. A method for dynamically controlling airflow in an electronic device includes determining, by an airflow controller in an electronic device, an operational mode of an electronic device, and switching, a controllable active cooling system in the electronic device by the airflow controller, to an airflow direction associated with the determined operational mode of the electronic device.

### TECHNICAL FIELD

This disclosure relates to electronic devices. More specifically, thermal management in the electronic devices.

### BACKGROUND

Electronic devices, such as but not limited to, access points, routers, servers, desktop computers, and/or gaming computers, include a number of electronic components in the housing that can generate heat as a byproduct of their operation. The electronic components can be cooled using one or more of passive cooling techniques and active cooling techniques. Passive cooling techniques can use heat sinks and heat spreaders to dissipate the heat away from the electronic components and the housing. Active cooling techniques can use fans or blowers to direct air across the electronic components for higher thermal transfer away from the electronic components and the housing.

Electronic devices and/or systems that are cooled actively by fans are typically configured for the fan to blow in a single direction. System design usually reflects this and chooses to place high heat components near the fan inlet to receive the most benefit from cool air before it passes over other hot components. This is adequate when the system has several electronic components that generate heat all of the time. However, if a system is complex enough that high heat electronic components must be distributed in different parts of the housing, then some of these electronic components may not receive sufficient cooling. This may lead to early onset of device and/or electronic device diminished performance and/or failure.

### SUMMARY

Disclosed is a system and method for intelligent, dynamic active cooling for electronic devices.

In implementations, a method for dynamically controlling airflow in an electronic device includes determining, by an airflow controller in an electronic device, an operational mode of an electronic device, and switching, a controllable active cooling system in the electronic device by the airflow controller, to an airflow direction associated with the determined operational mode of the electronic device.

### BRIEF DESCRIPTION OF THE DRAWINGS

The disclosure is best understood from the following detailed description when read in conjunction with the accompanying drawings. It is emphasized that, according to common practice, the various features of the drawings are not to scale. On the contrary, the dimensions of the various features are arbitrarily expanded or reduced for clarity.

FIG. 1 and FIG. 2 are diagrams of an example air flow issue.

FIG. 3 is a diagram of an example electronic device and service provider system in accordance with embodiments of this disclosure.

FIGS. 4 and 5 are diagrams of an example electronic device with dynamic active cooling in accordance with embodiments of this disclosure.

FIG. 6 is a diagram of an example electronic device with temperature sensors in accordance with embodiments of this disclosure.

FIG. 7 is a flowchart of an example method for dynamic active cooling in accordance with embodiments of this disclosure.

FIG. 8 is a block diagram of an example of a device in accordance with embodiments of this disclosure.

### DETAILED DESCRIPTION

Reference will now be made in greater detail to embodiments, examples of which are illustrated in the accompanying drawings. Wherever possible, the same reference numerals will be used throughout the drawings and the description to refer to the same or like parts.

As used herein, the terminology “server”, “computer”, “computing device or platform”, or “cloud computing system” includes any unit, or combination of units, capable of performing any method, or any portion or portions thereof, disclosed herein. For example, the “server”, “computer”, “computing device or platform”, or “cloud computing system” may include at least one or more processor(s).

As used herein, the terminology “processor” or “processing circuitry” indicates one or more processors, such as one or more special purpose processors, one or more digital signal processors, one or more microprocessors, one or more controllers, one or more microcontrollers, one or more application processors, one or more central processing units (CPU) s, one or more graphics processing units (GPU) s, one or more digital signal processors (DSP) s, one or more application specific integrated circuits (ASIC) s, one or more application specific standard products, one or more field programmable gate arrays, any other type or combination of integrated circuits, one or more state machines, or any combination thereof.

As used herein, the term “engine” may include software, hardware, or a combination of software and hardware. An engine may be implemented using software stored in the memory subsystem. Alternatively, an engine may be hard-wired into processing circuitry. In some cases, an engine includes a combination of software stored in the memory and hardware that is hard-wired into the processing circuitry.

As used herein, the terminology “memory” indicates any computer-usable or computer-readable medium or device that can tangibly contain, store, communicate, or transport any signal or information that may be used by or in connection with any processor. For example, a memory may be one or more read-only memories (ROM), one or more random access memories (RAM), one or more registers, low power double data rate (LPDDR) memories, one or more cache memories, one or more semiconductor memory devices, one or more magnetic media, one or more optical media, one or more magneto-optical media, or any combination thereof.

As used herein, the term “memory” includes one or more memories, where each memory may be a computer-readable medium. A memory may encompass memory hardware units (e.g., a hard drive or a disk) that store data or instructions in software form. Alternatively or in addition, the memory may include data or instructions that are hard-wired into processing circuitry. The memory may include a single memory unit or multiple joint or disjoint memory units, which each of the multiple joint or disjoint memory units storing all or a portion of the data described as being stored in the memory.

As used herein, the terminology “instructions” may include directions or expressions for performing any method, or any portion or portions thereof, disclosed herein, and may be realized in hardware, software, or any combination thereof. For example, instructions may be implemented as information, such as a computer program, stored in memory that may be executed by a processor to perform any of the respective methods, algorithms, aspects, or combinations thereof, as described herein. For example, the memory can be non-transitory. Instructions, or a portion thereof, may be implemented as a special purpose processor, or circuitry, that may include specialized hardware for carrying out any of the methods, algorithms, aspects, or combinations thereof, as described herein. In some implementations, portions of the instructions may be distributed across multiple processors on a single device, on multiple devices, which may communicate directly or across a network such as a local area network, a wide area network, the Internet, or a combination thereof.

As used herein, the term “application” refers generally to a unit of executable software that implements or performs one or more functions, tasks, or activities. For example, applications may perform one or more functions including, but not limited to, telephony, web browsers, e-commerce transactions, media players, scheduling, management, smart home management, entertainment, and the like. The unit of executable software generally runs in a predetermined environment and/or a processor.

As used herein, the terminology “determine” and “identify,” or any variations thereof includes selecting, ascertaining, computing, looking up, receiving, determining, establishing, obtaining, or otherwise identifying or determining in any manner whatsoever using one or more of the devices and methods are shown and described herein.

As used herein, the terminology “example,” “the embodiment,” “implementation,” “aspect,” “feature,” or “element” indicates serving as an example, instance, or illustration. Unless expressly indicated, any example, embodiment, implementation, aspect, feature, or element is independent of each other example, embodiment, implementation, aspect, feature, or element and may be used in combination with any other example, embodiment, implementation, aspect, feature, or element.

As used herein, the terminology “or” is intended to mean an inclusive “or” rather than an exclusive “or.” That is, unless specified otherwise, or clear from context, “X includes A or B” is intended to indicate any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from the context to be directed to a singular form.

As used herein, unless explicitly stated otherwise, any term specified in the singular may include its plural version. For example, “a computer that stores data and runs software,” may include a single computer that stores data and runs software or two computers-a first computer that stores data and a second computer that runs software. Also “a computer that stores data and runs software,” may include multiple computers that together stored data and run software. At least one of the multiple computers stores data, and at least one of the multiple computers runs software.

Further, for simplicity of explanation, although the figures and descriptions herein may include sequences or series of steps or stages, elements of the methods disclosed herein may occur in various orders or concurrently. Additionally, elements of the methods disclosed herein may occur with other elements not explicitly presented and described herein. Furthermore, not all elements of the methods described herein may be required to implement a method in accordance with this disclosure and claims. Although aspects, features, and elements are described herein in particular combinations, each aspect, feature, or element may be used independently or in various combinations with or without other aspects, features, and elements.

Further, the figures and descriptions provided herein may be simplified to illustrate aspects of the described embodiments that are relevant for a clear understanding of the herein disclosed processes, machines, and/or manufactures, while eliminating for the purpose of clarity other aspects that may be found in typical similar devices, systems, and methods. Those of ordinary skill may thus recognize that other elements and/or steps may be desirable or necessary to implement the devices, systems, and methods described herein. However, because such elements and steps do not facilitate a better understanding of the disclosed embodiments, a discussion of such elements and steps may not be provided herein. However, the present disclosure is deemed to inherently include all such elements, variations, and modifications to the described aspects that would be known to those of ordinary skill in the pertinent art in light of the discussion herein.

Active cooling devices in electronic devices are configured to move air in one direction or the other. For example, the air can be moved from side to side, top to bottom, and bottom to top. Certain electronic components in an electronic device can generate more heat than other electronic components. As the electronic components are placed in the housing of the electronic device or on a printed circuit board (PCB) that is placed in the housing and/or electronic device, the locations of the electronic components are important for how the airflow within the housing is oriented. However, static airflow directions can result in issues.

In an illustrative example, assume the active cooling device, such as a fan, is configured in a bottom to top airflow. Transmitter power amplifiers are typically located at the top of the PCB in a tower design. Therefore, as the forced air rises past other components in the housing, the forced air heats up. By the time the forced air reaches the PAs, the forced air is already hot. This, in turn, lowers the effectiveness of the heat transfer.

In another illustrative example, assume the active cooling device, such as a fan, is configured in a top to bottom airflow. Fans, Ethernet controlling chipsets, and/or integrated battery packs are typically located at the bottom of the PCB in a tower design. Therefore, as the forced air lowers past other components in the housing, the forced air heats up. By the time the forced air reaches the Fans, the Ethernet controlling chipsets, and/or the integrated battery packs, the forced air is already hot. As before, this lowers the effectiveness of the heat transfer.

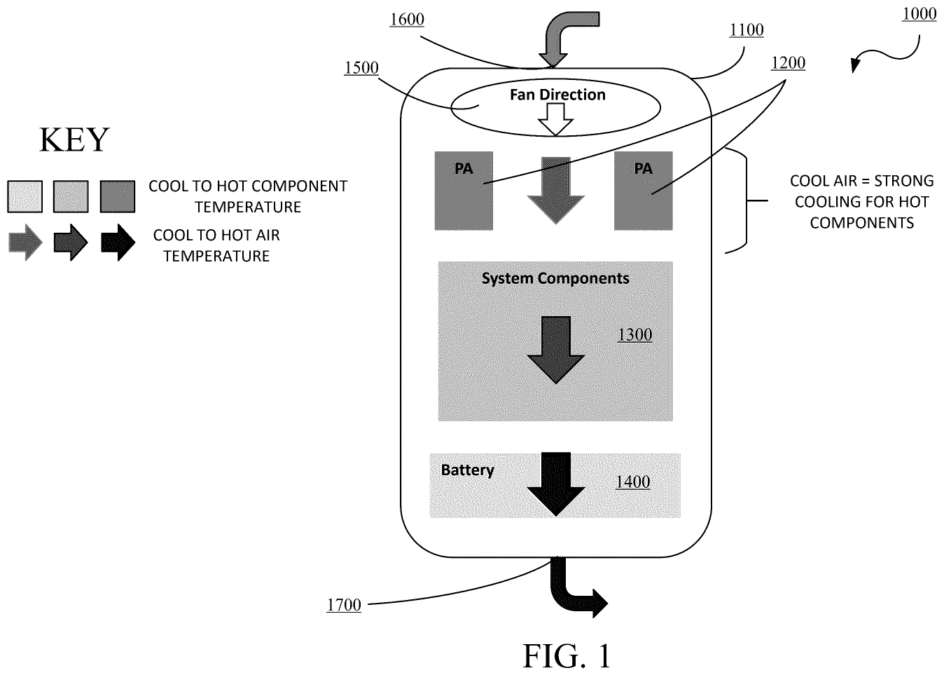

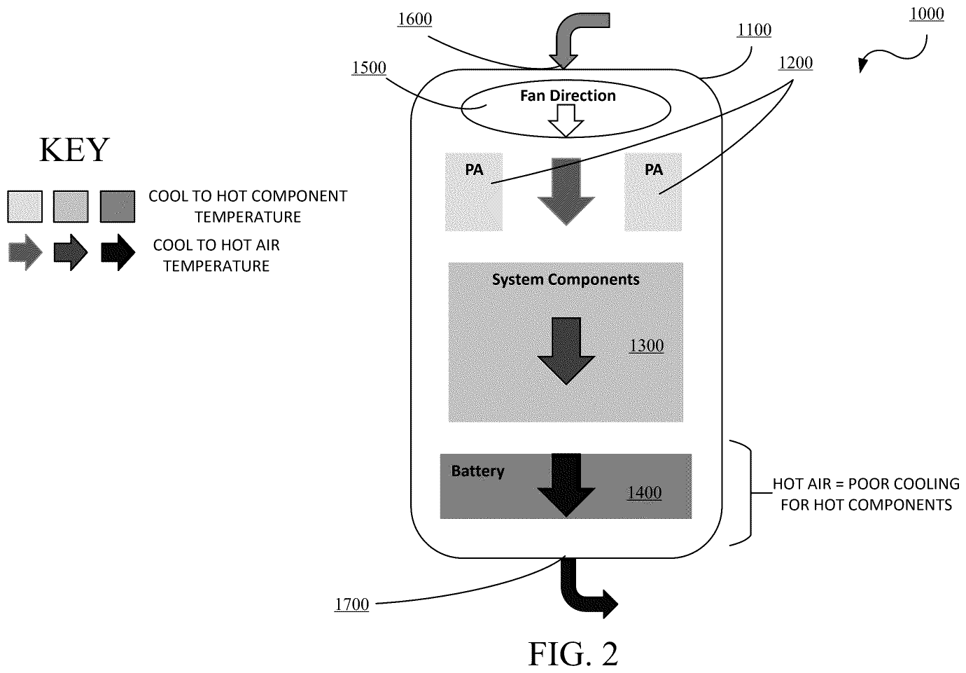

FIG. 1 and FIG. 2 are illustrative diagrams of examples of air flow issues in an electronic device 1000. The electronic device 1000 can include, but is not limited to, a housing 1100, power amplifiers 1200, system components 1300, a battery 1400, active cooling device 1500, an inlet 1600, and an outlet 1700. In this instance, electronic components can refer to the power amplifiers 1200, the system components 1300, and the battery 1400. The active cooling device 1500 can refer to and/or include, but is not limited to, fans and/or blowers. In this illustrative example, the active cooling 1500 is a fan.

In the illustrative example of FIG. 1, the power amplifiers 1200 are active and the battery 1400 is in standby or low power mode. The active cooling device 1500 forces cool air from the inlet 1600 toward the outlet 1700. The forced cool air can provide strong cooling for the hot components, i.e., the power amplifiers 1200. However, this airflow direction becomes problematic for the illustrative example of FIG. 2. In this instance, the power amplifiers are in standby or low power mode and the battery is active. As the forced cool air moves from the inlet 1600 toward the outlet 1700, the forced cool air becomes heated up. Therefore, when the heated up air reaches the battery 1400, the heated up air provides poor cooling with respect to the battery 1400.

The illustrated issues exist as most electronic devices, such as access points, are designed for airflow in one direction. When the fan is operating, the components that are downwind from the air intake have less ability to transfer heat to the already hot air. These components will be operating at a higher temperature, which may reduce performance and lifespan.

Described herein are devices, systems, and methods for intelligent and dynamic active cooling in electronic devices and/or systems. In implementations, electronic devices can include a controllable active cooling device and an airflow controller. The airflow controller can provide intelligence to switch the airflow direction of the controllable active cooling device depending on which electronic components require or will require temperature reductions. In implementations, the airflow controller can switch the airflow based on an operational mode or use case (collectively “operational mode”) of the electronic device, temperature sensor readings, and/or combinations thereof.

In implementations, the electronic devices can include temperature sensors, which can collectively work with the airflow controller to monitor electronic component temperatures and switch the airflow direction of the controllable active cooling device as needed.

In implementation, the airflow controller can be configured with a set of operational modes, where each operational mode can be associated with an airflow direction of the controllable active cooling device. In implementations, the airflow direction for each operational mode in an electronic device can be determined at the service provider using temperature probes, temperature sensors, and/or combinations thereof to obtain temperature measurements for each operational mode. In implementations, machine learning techniques can be used for configuration updates. In implementations, machine learning models can be trained using the set of operational modes, the temperature measurements, and the airflow directions. In implementations, updates to the set of operational modes and associated airflow directions can be made using the trained machine learning models and real-time and/or aggregated temperature measurements when the electronic device is in the field and being used.

In implementations, the devices, systems, and methods can increase the flexibility of the active cooling system to provide better thermal performance based on enhanced active cooling logic. This may be done without the cost of additional components. In implementations, the devices, systems, and methods can result in enhance thermal performance, higher peak absolute performance, longer sustained peak performance before thermal throttling, longer component life, and lower fan RPM, which can result in quieter operation.

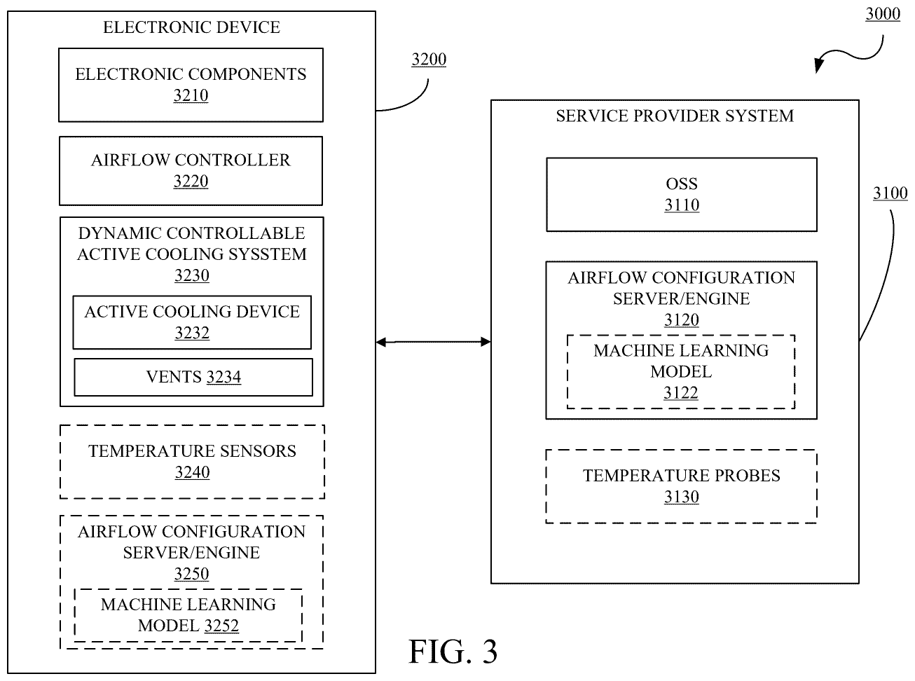

FIG. 3 is a diagram of an example architecture 3000 in accordance with embodiments of this disclosure. The architecture 3000 can include, but is not limited to, a service provider system 3100 and an electronic device 3200. The number of components shown herein are illustrative and there may be more or less in the architecture 3000. The architecture 3000 and the components therein may include other elements which may be desirable or necessary to implement the devices, systems, and methods described herein. However, because such elements and steps do not facilitate a better understanding of the disclosed embodiments, a discussion of such elements and steps may not be provided herein.

The service provider system 3100 can include, but is not limited to, an operations support system (OSS) 3110 and an airflow configuration server and/or engine 3120. In implementations, the service provider system 3100 can include, but is not limited to, temperature probes 3130.

The electronic device 3200 can include, but is not limited to, electronic components 3210, an airflow controller 3220, and a dynamic controllable active cooling system or configurable active cooling system 3230. In implementations, the electronic device 3200 can include, but is not limited to, temperature sensors 3240. In implementations, the electronic device 3200 can include, but is not limited to, an airflow configuration server and/or engine 3250.

The OSS 3110 can work with the airflow configuration server and/or engine 3120 and the other components in the service provider system 3100 to provide airflow configuration data to the electronic device 3200 and/or the airflow controller 3220. In implementations, the OSS 2100 can provide the airflow configuration data at electronic device initialization. In implementations, the OSS 2100 can provide updated airflow configuration data on-demand, defined intervals, and/or combinations thereof. In implementations, the airflow configuration data can include, but is not limited to, operational modes, airflow direction, revolutions per minute (RPM) settings, and/or electronic component location and/or layout. In implementations, the airflow configuration data can be maintained in a variety of formats including, but not limited to, a tabular format (e.g., operational mode table), data structure, and/or combinations thereof.

The airflow configuration server and/or engine 3120 can work with sensors and/or probes including, but not limited to, the temperature probes 3130, the temperature sensors 3240, and/or combinations thereof to obtain and collect temperature measurements from the electronics device 3200 as the electronics device 3200 is cycled through operational modes. During testing, the airflow configuration server and/or engine 3120 can use temperature measurements to determine cool to hot areas (a temperature gradient) for the electronics device 3200 when in the different operational modes. The airflow configuration server and/or engine 3120 can use the temperature gradient to determine an airflow direction for an operational mode. The airflow configuration server and/or engine 3120 can maintain a mapping of operational mode and airflow direction that can be provided to the electronics device 3200 and/or the airflow controller 3220 via the OSS 3100 as described herein. In implementations, each operational mode can be associated with an operational mode identifier which can be used by the airflow controller 3220 to control the airflow direction. In implementations, the operational modes, the temperature measurements, the temperature gradient, and the airflow direction can be used to train a machine learning model 3122. In implementations, the trained machine learning model 3122 can receive measurement data from the electronics device 3200 when in field use to generate and provide updated airflow configuration data to the electronics device 3200 and/or the airflow controller 3220.

The electronic components 3210 can include, but is not limited to, any number and type of devices including, but not limited to, active components, passive components, and/or combinations thereof.

The airflow controller 3220 can control the direction of the dynamic controllable active cooling system 3230 based on the airflow configuration data from the airflow configuration server and/or engine 3120 and the airflow controller's 3220 determination of what operational mode the electronic device 3200 is operating in. In implementations, the airflow controller 3220 can control the RPM of the dynamic controllable active cooling system 3230 based on the airflow configuration data from the airflow configuration server and/or engine 3120 and the airflow controller's 3220 determination of what operational mode the electronic device 3200 is operating in. In implementations, the airflow controller 3220 can be informed or obtain from the electronic device 3200 (e.g., main processor, operating system, and/or the like) of the operating mode. In an illustrative example, the electronic device 3200 can maintain a state table memory, use electrical readings within the electronic device 3200 (i.e., voltage rail for charging is high and therefore in battery charge mode, the DC input to the electronic device is low but the electronic device is still powered on and therefore the electronic device is operating off battery power). In implementations, the airflow controller 3220 can determine the operational mode based on temperature measurements from the temperature sensors 3240. In an illustrative example, the temperature measurements can indicate that the Ethernet interface is really hot, the power amplifiers are cool, and therefore the electronic device 3200 is transferring data over the Ethernet.

The dynamic controllable active cooling system 3230 can include, but is not limited to, an active cooling device 3232 and at least one pair of vents 3234 that can operate as inlets and/or outlets for the active cooling device 3232. In implementations, the active cooling device 3232 can be, but is not limited to, a fan, a blower, liquid cooling, and/or combinations thereof. In implementations, the at least one pair of vents 3234 can be adjusted based on the airflow direction. The airflow controller 3220 and the dynamic controllable active cooling system 3230 can include, but is not limited to, devices and circuits to control a direction of the active cooling device 3232. In implementations, the airflow controller 3220 and the dynamic controllable active cooling system 3230 can include, but is not limited to, devices and circuits to control a RPM of the active cooling device 3232. In implementations, the airflow controller 3220 and the dynamic controllable active cooling system 3230 can include, but is not limited to, devices and circuits to control adjustability of the at least one pair of vents 3234.

The temperature sensors 3240 can be, but is not limited to, thermistors, thermocouples, semiconductor-based sensors, and/or combinations thereof.

The airflow configuration server and/or engine 3250 and machine learning model 3252 can function as described for the airflow configuration server and/or engine 3120 and the machine learning model 3122 when the electronic device 3200 is being used in the field. The airflow configuration server and/or engine 3250 and the machine learning model 3252 can update the airflow controller 3220 on-demand, on a defined period or interval, and/or combinations thereof. In implementations, the machine learning model 3252 can be or can be trained by the machine learning model 3122.

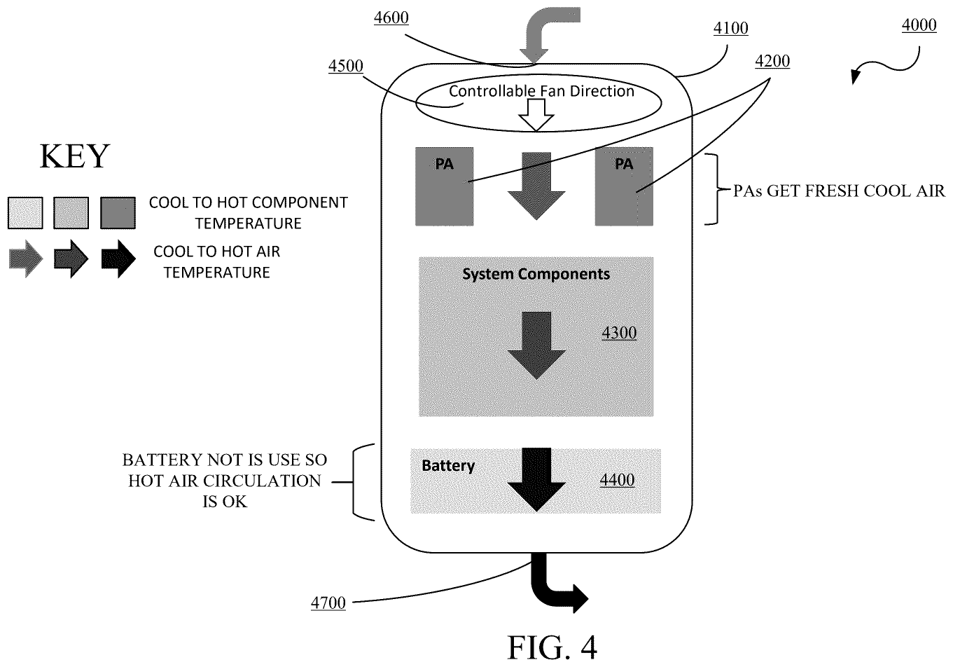

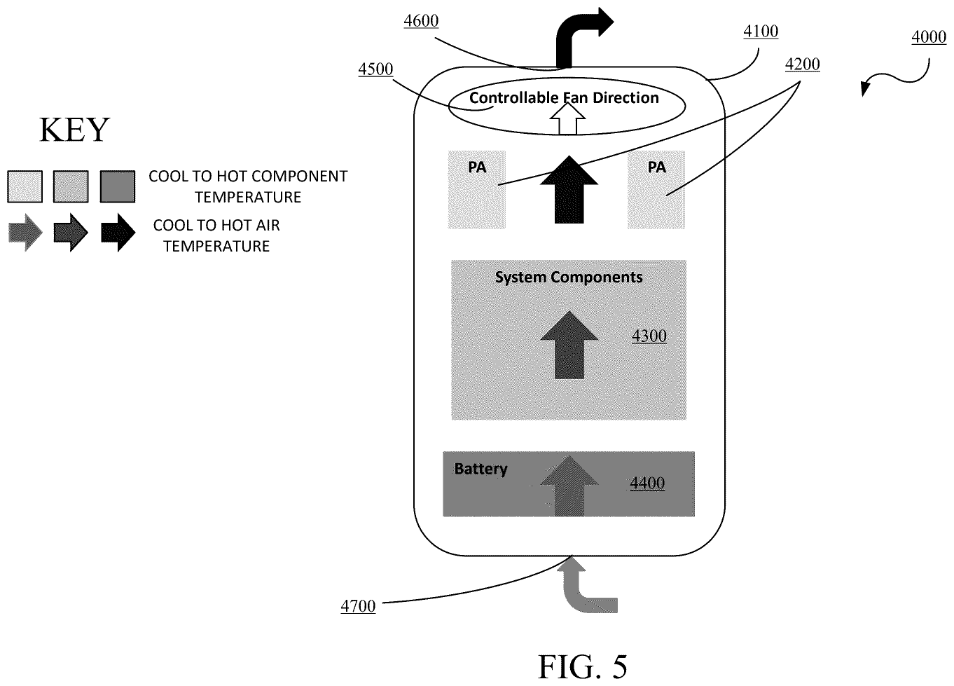

The electronic device 3200 is directed to providing the coldest air to the hottest components. The greater the difference in temperature between the air and the electronic component, the more effective the cooling will be. Operationally, this is described with reference to FIG. 3 as described herein, and FIGS. 4 and 5, which are diagrams of an example electronic device 4000 with dynamic active cooling in accordance with embodiments of this disclosure. The electronic device 4000 can include, but is not limited to, a housing 4100, power amplifiers 4200, system components 4300, a battery 4400, dynamic controllable active cooling device 4500, and a pair of vents 4600 and 4700. In this instance, electronic components can refer to the power amplifiers 4200, the system components 4300, and the battery 4400. The dynamic controllable active cooling device 4500 can be the dynamic controllable active cooling system 3230. The electronic device 4000 can refer to the electronic device 3200 and/or include the components described therein as applicable and appropriate.

In the illustrative example of FIG. 4, the electronic device 4000 can be an access point. In this operational mode, the electronic device 4000 can be performing high throughput WiFi streaming which generates significant heat across the power amplifiers 4200 (i.e., the power amplifiers 4200 are active) and the battery 4400 is in standby or low power mode. The airflow controller 3220 can determine the operational mode based on input from or obtained from the electronic device 4000, temperature measurements, machine learning models, and/or combinations thereof as described herein. The airflow controller 3220 can configure the dynamic controllable active cooling device 4500 and the pair of vents 4600 and 4700 to provide cool air across the power amplifiers 4200. In this instance, providing warmer air at the battery 4400 is not as critical as the battery 4400 is in standby or low power mode.

In the operational mode of FIG. 5, the battery 4400 of the electronic device 4000 can be charging or the electronic device 4000 is operating off of the battery power. In this instance, the battery 4400 generates significant heat but the power amplifiers 4200 are not being pushed or driven as in the streaming case and therefore not a significant source of heat. As before, the airflow controller 3220 can determine the operational mode based on input from or obtained from the electronic device 4000, temperature measurements, machine learning models, and/or combinations thereof as described herein. The airflow controller 3220 can configure the dynamic controllable active cooling device 4500 and the pair of vents 4600 and 4700 to provide cool air across the battery 4400. In this instance, providing warmer air at the power amplifiers 4200 is not as critical.

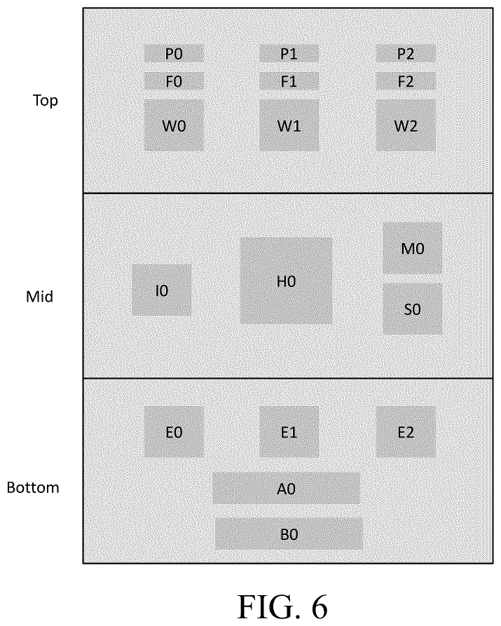

FIG. 6 is a diagram of an example a printed circuit board 6000 with electronic components and temperature sensors in accordance with embodiments of this disclosure. The layout and location of the electronic components and associated temperature sensors are illustrative examples and a variety of layouts and locations can be implemented. The printed circuit board (PCB) 6000 can be in the electronic device 3200 of FIG. 3 and/or the electronic device 4000 of FIGS. 4 and 5. In implementations, the printed circuit board 6000 can include, but is not limited to, a top portion 6100, a middle portion 6200, and a bottom portion 6300. In these illustrative examples, the top portion 6100 can include, but is not limited to, wireless components with associated temperature sensors P0, P1, P2, F0, F1, F2, W0, W1, and W2, the middle portion 6200 can include, but is not limited to, core components with associated temperature sensors I0, H0, M0, and S0, and the bottom portion 6200 can include, but is not limited to, network components with associated temperature sensors E0, E1, and E2, dynamic controllable active cooling device A0, and battery B0. The type of electronic components, the location on the PCB 6000, and a recommended airflow direction can be maintained on the electronic device as shown, for example, in Table 1 and Table 2 below. This data can be used by the airflow controller, the airflow configuration server and/or engine, and the machine learning model to identify operational mode and select airflow direction. In implementations, each of the electronic components can have an operational temperature range, a critical temperature, and/or other temperature based parameters (collectively “temperature parameters”). In implementations, the airflow controller, the airflow configuration server and/or engine, and the machine learning model can use these temperature parameters to prioritize cooling of an electronic component based on temperature measurements from the associated temperature sensor.

TABLE 1

| | ELECTRONIC | PCB | AIRFLOW |
|---|---|---|---|
| LABEL | COMPONENT | LOCATION | DIRECTION |
| W0 | WIFI MODULE 1 | TOP | TOP-TO-BOTTOM |
| W1 | WIFI MODULE 2 | TOP | TOP-TO-BOTTOM |
| W2 | WIFI MODULE 3 | TOP | TOP-TO-BOTTOM |
| F0 | FILTER 1 | TOP | TOP-TO-BOTTOM |
| F1 | FILTER 2 | TOP | TOP-TO-BOTTOM |
| F2 | FILTER 3 | TOP | TOP-TO-BOTTOM |
| P0 | FRONT-END | TOP | TOP-TO-BOTTOM |
| | MODULE 1 | | |
| P1 | FRONT-END | TOP | TOP-TO-BOTTOM |
| | MODULE 2 | | |
| P2 | FRONT-END | TOP | TOP-TO-BOTTOM |
| | MODULE 3 | | |
| H0 | PROCESSOR | MIDDLE | NO PREFERENCE |
| I0 | IOT MODULE | MIDDLE | NO PREFERENCE |
| M0 | MEMORY 1 | MIDDLE | NO PREFERENCE |
| S0 | MEMORY 2 | MIDDLE | NO PREFERENCE |
| E0 | NETWORK | BOTTOM | BOTTOM-TO-TOP |
| | MODULE 1 | | |
| E1 | NETWORK | BOTTOM | BOTTOM-TO-TOP |
| | MODULE 2 | | |
| E2 | NETWORK | BOTTOM | BOTTOM-TO-TOP |
| | MODULE 3 | | |
| A0 | DYNAMIC ACTIVE | BOTTOM | BOTTOM-TO-TOP |
| | COOLING DEVICE | | |
| B0 | BATTERY | BOTTOM | BOTTOM-TO-TOP |

TABLE 2

| OPERA- | | | |
|---|---|---|---|
| TIONAL | ELECTRONIC | PCB | AIRFLOW |
| MODE | COMPONENTS | LOCATION | DIRECTION |
| W0 | P0/P1/P2/W0/W1/W2 | TOP | TOP-TO-BOTTOM |
| W1 | E0/E1/E2 | BOTTOM | BOTTOM-TO-TOP |
| W2 | B0 | BOTTOM | BOTTOM-TO-TOP |
| F0 | H0 | MIDDLE | BOTTOM-TO-TOP |

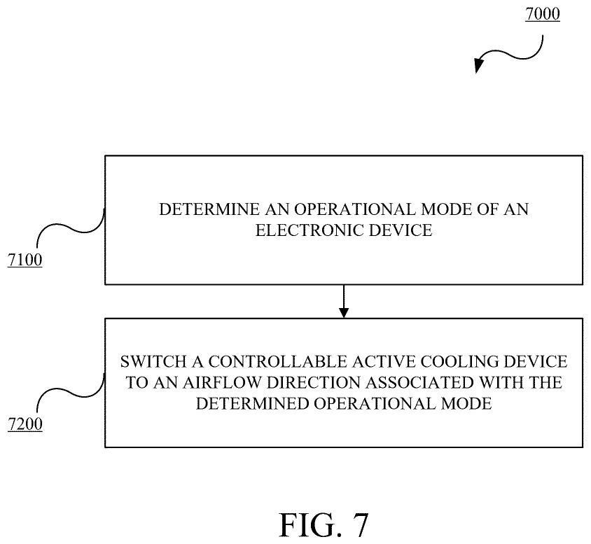

FIG. 7 is a flowchart of an example method 7000 for dynamically controlling airflow in an electronic device in accordance with embodiments of this disclosure. The method 7000 includes: determining 7100 an operational mode of an electronic device; and switching 7200 a controllable active cooling system to an airflow direction associated with the determined operational mode. The method 7000 can be implemented, for example, in or by components described with respect to FIGS. 3-6 and 8 and in conjunction with any of the flows described with respect to FIG. 7, as appropriate and applicable.

The method 7000 includes determining 7100 an operational mode of an electronic device. In implementations, an airflow controller can obtain or receive from the electronic device an operational mode of the electronic device. In implementations, the airflow controller in an electronic device can maintain operational mode tables for the electronic device. Each operational mode entry in the table can be associated with an airflow direction. In implementations, a service provider can run the electronic device through its operational modes, obtain temperature measurements, and determine an airflow direction. The electronic device can be configured with the operational modes and airflow direction. The airflow controller can select an appropriate airflow direction based on the determined operational mode of the electronic device. In implementations, the electronic device can include temperature sensors. The airflow controller can review temperature measurements from the temperature sensors to determine the operating mode. In an illustrative example, a determined cooling pattern for the electronic components based on the temperature measurements can be compared against electronic components in each of the operational modes as illustrated in Table 2. This can then be used to select the operational mode.

The method 7000 includes switching 7200 a controllable active cooling system to an airflow direction associated with the determined operational mode. The controllable active cooling system can include at least a controllable active cooling device and a pair of vents which can function as inlets and outlets depending on airflow direction. The airflow controller can control and/or instruct the controllable active cooling system to direct fresh (in contrast to heated or warmed up airflow) or cooler airflow toward electronic components associated with the determined operational mode.

In implementations of the method 7000, the airflow controller can maintain temperature performance parameters for the electronic components in the electronic device. The airflow controller can switch the airflow direction to prioritize cooling of an electronic component that is going to breach or has breached one or more temperature performance parameters. This can be based on temperature measurements received from the temperature sensors.

In implementations of the method 7000, trained machine learning models at a service provider, on the electronic device, and/or combinations thereof can learn during operation of the electronic device using the operational mode, temperature measurements, electronic component layout, and update the operational mode tables, as appropriate.

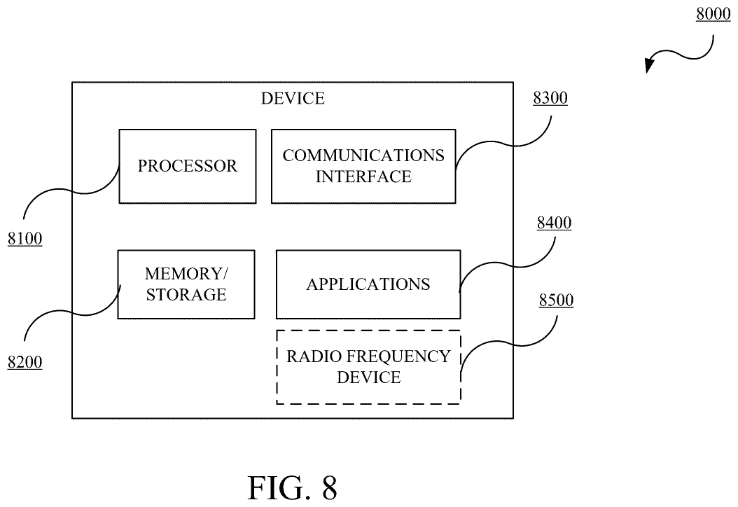

FIG. 8 is a block diagram of an example of a device 8000 in accordance with embodiments of this disclosure. The device 8000 may include, but is not limited to, a processor 8100, a memory/storage 8200, a communication interface 8300, applications 8400, and, if needed, a radio frequency device 8500. The device 8000 may include or implement, for example, the systems and components described with respect to FIGS. 3-6 and the implement the methods of FIG. 7. The applicable or appropriate flows, techniques, or methods described herein may be stored in the memory/storage 8200 and executed by the processor 8100 in cooperation with the memory/storage 8200, the communications interface 8300, the applications 8400, and the radio frequency device 8500 (when applicable), as appropriate. The device 8000 may include other elements which may be desirable or necessary to implement the devices, systems, and methods described herein. However, because such elements and steps do not facilitate a better understanding of the disclosed embodiments, a discussion of such elements and steps may not be provided herein.

Described herein is a method for intelligent, dynamic active cooling for electronic devices. In implementations, a method for dynamically controlling airflow in an electronic device includes determining, by an airflow controller in an electronic device, an operational mode of an electronic device, and switching, a controllable active cooling system in the electronic device by the airflow controller, to an airflow direction associated with the determined operational mode of the electronic device.

In implementations, the method further includes configuring, the airflow controller via an operations support system, with airflow configuration data. In implementations, the method further includes selecting, by the airflow controller, the airflow direction from airflow configuration data, wherein the airflow configuration data includes operational modes and associated airflow directions. In implementations, the method further includes updating, the airflow controller via a machine learning model trained on the operational modes and the airflow direction, the airflow configuration data. In implementations, the determining further includes receiving, by the airflow controller from the electronic device, the operational mode of the electronic device. In implementations, the determining further includes receiving, by the airflow controller from temperature sensors in the electronic device, temperature measurements for electronic components in the electronic device, and determining, by the airflow controller, the operational mode from the received temperature measurements. In implementations, the method further includes configuring, the airflow controller via the operations support system, with temperature performance parameters for electronic components in the electronic device, receiving, by the airflow controller from temperature sensors in the electronic device, temperature measurements for the electronic components, and switching, the controllable active cooling system by the airflow controller, the airflow direction based on an electronic component breaching one or more temperature performance parameters associated with the electronic component. In implementations, the method further includes configuring, the airflow controller via the operations support system, with temperature performance parameters for electronic components in the electronic device, and prioritizing, by the airflow controller, cooling of an electronic component breaching one or more temperature performance parameters associated with the electronic component.

Described herein is a device for intelligent, dynamic active cooling for electronic devices. In implementations, an electronic device includes electronic components, a configurable active cooling system, and an airflow controller connected to the configurable active cooling system. The airflow controller is configured to identify a use case of the electronic device, and configure the configurable active cooling system to direct a fresh airflow toward certain of the electronic components associated with the use case. In implementations, the electronic device further includes memory to maintain airflow configuration data received from a configuration server. In implementations, the electronic device further includes an airflow configuration server configured to update the airflow configuration data via a machine learning model trained on use cases and the airflow directions. In implementations, the airflow controller further configured to choose the airflow direction from airflow configuration data, wherein the airflow configuration data includes use cases and associated airflow directions. In implementations, the airflow controller further configured to obtain the use case from the electronic device. In implementations, the electronic device further includes temperature sensors for each of the electronic components, and the airflow controller further configured to obtain temperature measurements for the electronic components from the temperature sensors, and determine the use case from the received temperature measurements. In implementations, the electronic device further includes memory to maintain temperature performance parameters for each of electronic components, and the airflow controller further configured to obtain temperature measurements for the electronic components from the temperature sensors, and command the configurable active cooling system to direct airflow toward an electronic component breaching one or more temperature performance parameters associated with the electronic component.

Described herein is a method for intelligent, dynamic active cooling for electronic devices. In implementations, a method for dynamically controlling airflow in an electronic device includes maintaining, by an airflow controller in an electronic device, airflow configuration data, wherein the airflow configuration data includes operational modes and associated airflow directions, determining, by the airflow controller, an operational mode of the electronic device, selecting, by the airflow controller, an airflow direction from the airflow configuration data based on the determined operational mode, and instructing, a controllable active cooling system in the electronic device by the airflow controller, to direct airflow in the selected airflow direction. In implementations, the method further includes updating, via a machine learning model trained on operational modes and airflow directions, the airflow configuration data. In implementations, the method further includes obtaining, by the airflow controller from the electronic device, the operational mode of the electronic device. In implementations, the determining further includes receiving, by the airflow controller from temperature sensors in the electronic device, temperature measurements for electronic components in the electronic device, and determining, by the airflow controller, the operational mode from the received temperature measurements. In implementations, the method further includes configuring, the airflow controller via the operations support system, with temperature performance parameters for electronic components in the electronic device, and prioritizing, by the airflow controller, cooling of an electronic component breaching one or more temperature performance parameters associated with the electronic component. In implementations, the method further includes setting, by the airflow controller, a revolutions per minute of the controllable active cooling system based on the airflow configuration data.

Although some embodiments herein refer to methods, it will be appreciated by one skilled in the art that they may also be embodied as a system or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “processor,” “device,” or “system.” Furthermore, aspects may take the form of a computer program product embodied in one or more the computer readable mediums having the computer readable program code embodied thereon. For example, the computer readable mediums can be non-transitory. Any combination of one or more computer readable mediums may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electromagnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to CDs, DVDs, wireless, wireline, optical fiber cable, RF, etc., or any suitable combination of the foregoing.

As used herein, the term “computer-readable medium” encompasses one or more computer-readable media. A computer-readable medium may include any storage unit (or multiple storage units) that store data or instructions that are readable by processing circuitry. A computer-readable medium may include, for example, at least one of a data repository, a data storage unit, a computer memory, a hard drive, a disk, or a random access memory. A computer-readable medium may include a single computer-readable medium or multiple computer-readable media. A computer-readable medium may be a transitory computer-readable medium or a non-transitory computer-readable medium.

Computer program code for carrying out operations for aspects may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects are described herein with reference to flowchart illustrations and/or block diagrams of methods, apparatus (systems) and computer program products according to embodiments. It will be understood that each block of the flowchart illustrations and/or block diagrams, and combinations of blocks in the flowchart illustrations and/or block diagrams, can be implemented by computer program instructions.

These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowcharts and block diagrams in the figures illustrate the architecture, functionality, and operation of possible implementations of systems, methods, and computer program products according to various embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures.

While the disclosure has been described in connection with certain embodiments, it is to be understood that the disclosure is not to be limited to the disclosed embodiments but, on the contrary, is intended to cover various modifications, combinations, and equivalent arrangements included within the scope of the appended claims, which scope is to be accorded the broadest interpretation so as to encompass all such modifications and equivalent structures as is permitted under the law.

What is claimed is:

1. A method for dynamically controlling airflow in an electronic device, the method comprising:
determining, by an airflow controller in an electronic device, an operational mode of an electronic device; and
switching, a controllable active cooling system in the electronic device by the airflow controller, to an airflow direction associated with the determined operational mode of the electronic device.

2. The method of claim 1, further comprising:
configuring, the airflow controller via an operations support system, with airflow configuration data.

3. The method of claim 2, further comprising:
selecting, by the airflow controller, the airflow direction from airflow configuration data, wherein the airflow configuration data includes operational modes and associated airflow directions.

4. The method of claim 2, further comprising:
updating, the airflow controller via a machine learning model trained on the operational modes and the airflow direction, the airflow configuration data.

5. The method of claim 1, wherein the determining further comprising:
receiving, by the airflow controller from the electronic device, the operational mode of the electronic device.

6. The method of claim 1, wherein the determining further comprising:
receiving, by the airflow controller from temperature sensors in the electronic device, temperature measurements for electronic components in the electronic device; and
determining, by the airflow controller, the operational mode from the received temperature measurements.

7. The method of claim 1, further comprising:
configuring, the airflow controller via the operations support system, with temperature performance parameters for electronic components in the electronic device;
receiving, by the airflow controller from temperature sensors in the electronic device, temperature measurements for the electronic components; and
switching, the controllable active cooling system by the airflow controller, the airflow direction based on an electronic component breaching one or more temperature performance parameters associated with the electronic component.

8. The method of claim 1, further comprising:
configuring, the airflow controller via the operations support system, with temperature performance parameters for electronic components in the electronic device; and
prioritizing, by the airflow controller, cooling of an electronic component breaching one or more temperature performance parameters associated with the electronic component.

9. An electronic device, comprising:
electronic components;
a configurable active cooling system; and
an airflow controller connected to the configurable active cooling system, wherein the airflow controller is configured to:
identify a use case of the electronic device; and
configure the configurable active cooling system to direct a fresh airflow toward certain of the electronic components associated with the use case.

10. The device of claim 9, further comprising:
memory to maintain airflow configuration data received from a configuration server.

11. The device of claim 10, further comprising:
airflow configuration server configured to update the airflow configuration data via a machine learning model trained on use cases and the airflow directions.

12. The device of claim 9, the airflow controller further configured to:
choose the airflow direction from airflow configuration data, wherein the airflow configuration data includes use cases and associated airflow directions.

13. The device of claim 9, the airflow controller further configured to:
obtain the use case from the electronic device.

14. The device of claim 9, further comprising:
temperature sensors for each of the electronic components; and
the airflow controller further configured to:
obtain temperature measurements for the electronic components from the temperature sensors; and
determine the use case from the received temperature measurements.

15. The device of claim 9, further comprising:
memory to maintain temperature performance parameters for each of electronic components; and
the airflow controller further configured to:
obtain temperature measurements for the electronic components from the temperature sensors; and
command the configurable active cooling system to direct airflow toward an electronic component breaching one or more temperature performance parameters associated with the electronic component.

16. A method for dynamically controlling airflow in an electronic device, the method comprising:
maintaining, by an airflow controller in an electronic device, airflow configuration data, wherein the airflow configuration data includes operational modes and associated airflow directions;
determining, by the airflow controller, an operational mode of the electronic device;
selecting, by the airflow controller, an airflow direction from the airflow configuration data based on the determined operational mode; and
instructing, a controllable active cooling system in the electronic device by the airflow controller, to direct airflow in the selected airflow direction.

17. The method of claim 16, further comprising:
updating, via a machine learning model trained on operational modes and airflow directions, the airflow configuration data.

18. The method of claim 16, further comprising:
obtaining, by the airflow controller from the electronic device, the operational mode of the electronic device.

19. The method of claim 16, wherein the determining further comprising:
receiving, by the airflow controller from temperature sensors in the electronic device, temperature measurements for electronic components in the electronic device; and
determining, by the airflow controller, the operational mode from the received temperature measurements.

20. The method of claim 16, further comprising:
configuring, the airflow controller via the operations support system, with temperature performance parameters for electronic components in the electronic device; and
prioritizing, by the airflow controller, cooling of an electronic component breaching one or more temperature performance parameters associated with the electronic component.

21. The method of claim 16, further comprising:
setting, by the airflow controller, a revolutions per minute of the controllable active cooling system based on the airflow configuration data.
